(19) United States
(12) Patent Application Publication
(10) Pub. No.: US 2016/0157337 A1
(43) Pub. Date: Jun. 2, 2016

(54) PRINTED CIRCUIT BOARD AND DISPLAY DEVICE HAVING THE SAME

(71) Applicant: Samsung Display Co., Ltd., Yongin-City (KR)

(72) Inventors: JeongHun GO, Asan-si (KR); Youngsun KIM, Asan-si (KR); SiYoung CHOI, Asan-si (KR)

(21) Appl. No.: 14/685,208

(22) Filed: Apr. 13, 2015

(30) Foreign Application Priority Data
Dec. 2, 2014 (KR) 10-2014-0170663

(51) Int. Cl. H05K 1/02; G09G 5/00

(52) U.S. Cl. CPC H05K 1/0224; G09G 5/00

(57) ABSTRACT

A printed circuit board includes a ground layer including a ground pattern, a pattern layer disposed on the ground layer and including a plurality of signal patterns, and a shielding layer disposed on the pattern layer and overlapping the signal patterns.

### CROSS-REFERENCE TO RELATED APPLICATION

This U.S. non-provisional patent application claims priority under 35 U.S.C. §119 of Korean Patent Application No. 10-2014-0170663, filed on Dec. 2, 2014, the contents of which are hereby incorporated by reference in its entirety.

### BACKGROUND

1. Field of disclosure

The present disclosure relates to a printed circuit board and a display device having the same. More particularly, the present disclosure relates to a printed circuit board capable of reducing electromagnetic interference and a display device having the printed circuit board.

2. Description of the Related Art

In general, a printed circuit board includes a plurality of parts mounted thereon and signal lines for transmitting signals among the parts. Data are transmitted at a high rate using the signal lines, and as such, the parts mounted on the printed circuit board have been developed to respond at high frequencies. An electromagnetic field induced by the flow of current is formed around each signal line through which the data are transmitted and exerts influence on a signal transmitting through an adjacent signal line. As a result, an electromagnetic interference (EMI) phenomenon that disturbs the operation of the parts occurs. Particularly, when a high frequency signal for high-speed operation of the parts is transmitted through the signal lines, the EMI phenomenon is intensified.

Since the frequency of data and control signals is high in a display device having a large size and high definition, the voltage swing width of the signals is large, and thus the EMI phenomenon is intense. For example, when a notebook computer is connected to a wireless wide area network (WWAN), a noise occurs in the signal being transmitted and received through the WWAN due to the EMI phenomenon.

### SUMMARY

The present disclosure provides a printed circuit board capable of reducing an EMI phenomenon.

The present disclosure provides a display device having the printed circuit board. Embodiments of the present system and method provide a printed circuit board including a ground layer including a ground pattern, a pattern layer disposed on the ground layer and including a plurality of signal patterns, and a shielding layer disposed on the pattern layer and overlapping the signal patterns.

The printed circuit board may further include a first insulating layer disposed between the ground layer and the pattern layer and a second insulating layer disposed between the pattern layer and the shielding layer.

The pattern layer may further include a signal ground pattern disposed to be insulated from the signal patterns.

The shielding layer may include a protective ground pattern that overlaps with the signal patterns. The printed circuit board may further include a timing controller disposed on the pattern layer and electrically connected to the signal patterns.

The signal patterns may include first signal patterns and second signal patterns, and the timing controller may be electrically connected to the first and second signal patterns.

The timing controller may output a plurality of image signals and a plurality of driving signals, which are used to display an image, through the first signal patterns.

The timing controller may receive a plurality of control signals and a plurality of image data from the outside thereof through the second signal patterns.

Embodiments of the present system and method provide a display device including a display panel displaying an image, a data driver electrically connected to the display panel and outputs a plurality of data voltages to display the image, and a printed circuit board generating a plurality of image signals corresponding to the data voltages and a plurality of driving signals. The printed circuit board includes a ground layer comprising a ground pattern, a pattern layer disposed on the ground layer and comprising a plurality of signal patterns, and a shielding layer disposed on the pattern layer and overlapping the signal patterns.

The data driver may be electrically connected to the signal patterns disposed on the pattern layer.

The shielding layer may include a protective ground pattern that overlaps with the signal patterns.

The printed circuit board may further include a timing controller to generate the image signals and the driving signals, and the timing controller is disposed on the pattern layer.

The timing controller may be electrically connected to the signal patterns and apply the image signals and the driving signals to the signal patterns.

The timing controller may apply the image signals and the driving signals to the signal patterns based on a differential signal.

The pattern layer may further include a signal protective pattern insulated from the signal patterns.

According to the above, the printed circuit board may reduce the EMI generated thereby. As a result, the driving reliability of the display device may be improved.

### BRIEF DESCRIPTION OF THE DRAWINGS

The above and other advantages of the present disclosure will become readily apparent when the following detailed description is considered in conjunction with the accompanying drawings wherein:

FIG. 1 is a perspective view showing a display device according to an exemplary embodiment of the present disclosure;

FIG. 2 is a block diagram showing the display device shown in FIG. 1;

FIG. 3 is a perspective view showing a printed circuit board shown in FIG. 1;

FIG. 4 is an exploded perspective view showing the printed circuit board shown in FIG. 3; and

FIG. 5 is a block diagram showing a pattern layer shown in FIG. 4.

### DETAILED DESCRIPTION

When an element or layer is referred to as being “on”, “connected to” or “coupled to” another element or layer, it may be directly on, connected or coupled to the other element or layer, or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

Although the terms first, second, etc. may be used herein to describe various elements, components, regions, layers and/or sections, these elements, components, regions, layers and/or sections are not limited by these terms. These terms are only used to distinguish one element, component, region, layer or section from another element, component, region, layer or section. Thus, a first element, component, region, layer or section discussed below may be referred to as a second element, component, region, layer or section without departing from the teachings of the present disclosure.

Spatially relative terms, such as “beneath”, “below”, “lower”, “above”, “upper” and the like, may be used herein for ease of description to describe one element or feature's relationship to another element(s) or feature(s) as illustrated in the figures. The spatially relative terms encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” encompasses both an orientation of above and below, depending on the orientation of the device relative to that shown in the figures. That is, in whichever way the device may be otherwise oriented (e.g., rotated 90 degrees or at other orientations), the spatially relative descriptors used herein are to be interpreted accordingly.

The terminology used herein for describing particular embodiments is not limiting of the present system and method. As used herein, the singular forms, “a”, “an” and “the” include the plural forms as well, unless the context clearly indicates otherwise. The terms “includes” and/or “including”, when used in this specification, specify the presence of stated features, integers, steps, operations, elements, and/or components, but do not preclude the presence or addition of one or more other features, integers, steps, operations, elements, components, and/or groups thereof

Unless otherwise defined, all terms (including technical and scientific terms) used herein have the meaning as commonly understood by one of ordinary skill in the art to which this disclosure belongs. That is, terms, including those defined in commonly used dictionaries, are to be interpreted as having a meaning that is consistent with their meaning in the context of the relevant art unless expressly so defined herein.

Hereinafter, the present system and method are explained in detail with reference to the accompanying drawings.

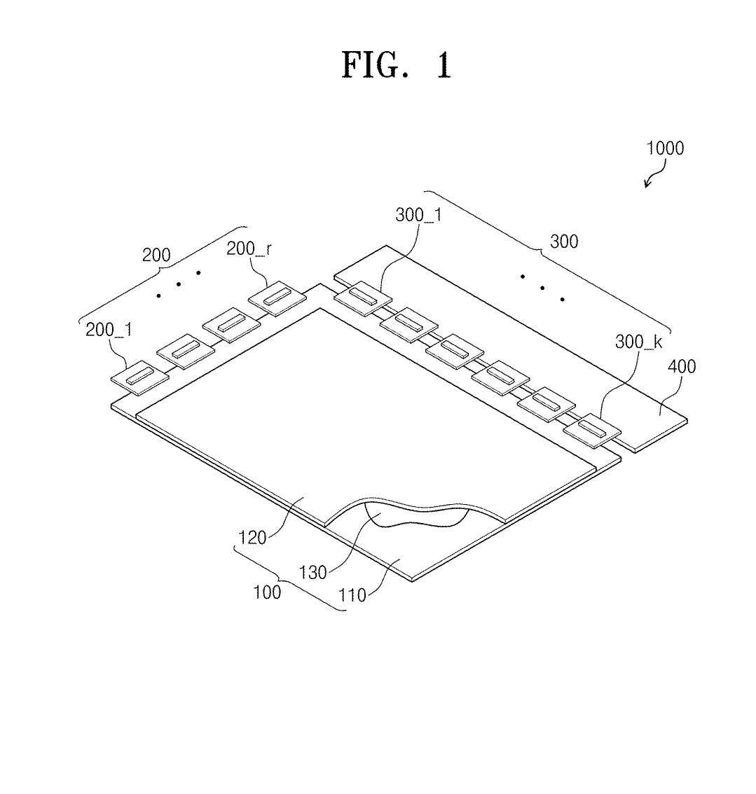

FIG. 1 is a perspective view showing a display device 1000 according to an exemplary embodiment of the present disclosure. Referring to FIG. 1, the display device includes a display panel 100, a gate driver 200, a data driver 300, and a printed circuit board 400.

The display panel 100 includes a first substrate 110, a second substrate 120, and a liquid crystal layer 130. The first substrate 110 includes a plurality of gate lines, a plurality of data lines, and a plurality of pixels to display an image.

The second substrate 120 includes a color filter (not shown) and a common electrode (not shown). According to another embodiment, the color filter may be included in the first substrate 110.

The liquid crystal layer 130 is disposed between the first substrate 110 and the second substrate 120. The liquid crystal layer 130 includes liquid crystal molecules that may be realigned by an electric field generated between a pixel electrode (not shown) disposed on the first substrate 110 and the common electrode. The amount of the light passing through the liquid crystal layer 130 is controlled by the realignment of the liquid crystal molecules. The gate driver 200 is disposed on the first substrate 110 and includes a plurality of gate circuit boards 200_1 to 200_r. Each of the gate circuit boards 200_1 to 200_r includes a gate driving chip. Each gate driving chip is electrically connected to the gate lines and applies a plurality of gate signals to the gate lines. The gate driver 200 is operated in response to a gate control signal received through the data driver 300. The data driver 300 is mounted on the first substrate 110 and includes a plurality of data circuit boards 300_1 to 300_k. Each data circuit board includes a data driving chip. Each data driving chip is electrically connected to the data lines and applies a plurality of data voltages corresponding to image signals to the data lines.

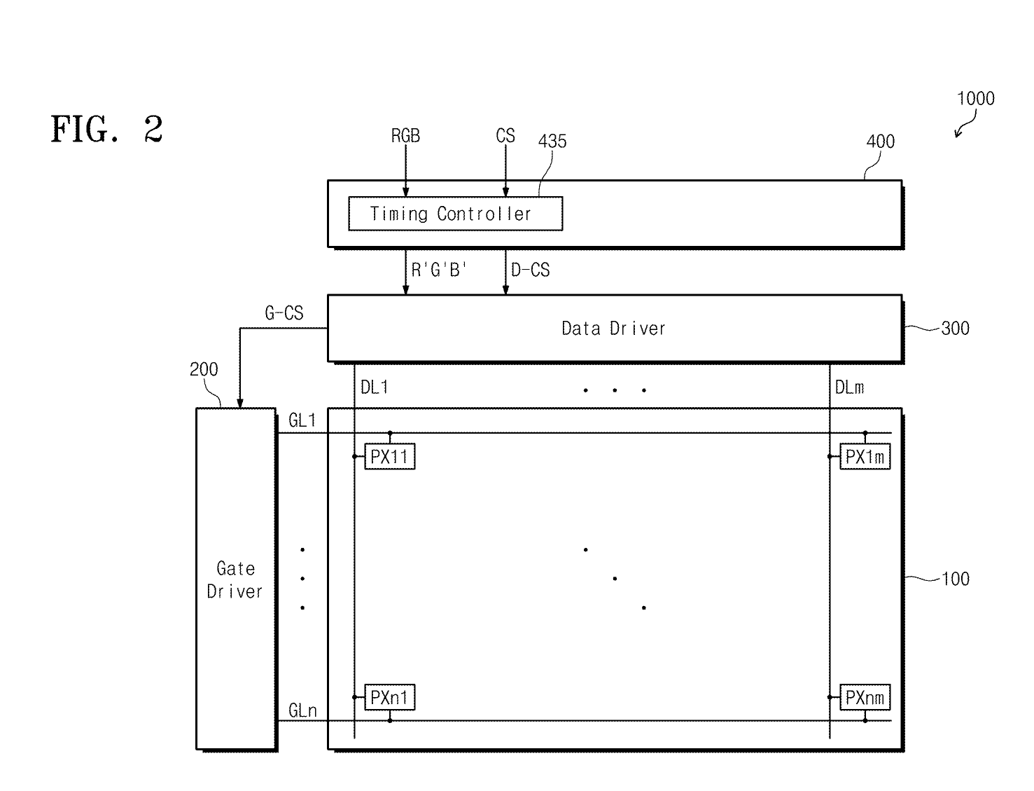

The printed circuit board 400 is electrically connected to the data circuit boards 300_1 to 300_k included in the data driver 300. The printed circuit board 400 generates a plurality of control signals and the image signals for displaying the image, and applies the control signals and the image signals to the gate driver 200 and the data driver 300. That is, the printed circuit board 400 controls the operations of the display device 1000 to display the image. FIG. 2 is a block diagram showing the display device 1000 shown in FIG. 1.

Referring to FIGS. 1 and 2, the display panel 100 includes the pixels PX11 to PXnm. The display panel 100 includes the gate lines GL1 to GLn and the data lines DL1 to DLm, which are insulated from the gate lines GL1 to GLn and cross the gate lines GL1 to GLn.

The gate lines GL1 to GLn are connected to the gate driver 200 and sequentially receive the gate signals. The data lines DL1 to DLm are connected to the data driver 300 and receive the data voltages.

The pixels PX11 to PXnm are arranged in areas defined in association with the gate lines GL1 to GLn and the data lines DL1 to DLm crossing the gate lines GL1 to GLn. Accordingly, the pixels PX11 to PXnm are arranged in a matrix form of n rows by m columns. Each of “n” and “m” is an integer number greater than zero.

Each of the pixels PX11 to PXnm is connected to a corresponding gate line of the gate lines GL1 to GLn and a corresponding data line of the data lines DL1 to DLm. Each of the pixels PX11 to PXnm receives a corresponding one of the data voltages provided through a corresponding one of the data lines DL1 to DLm in response to a corresponding one of the gate signals provided through a corresponding one of the gate lines GL1 to GLn. As a result, the pixels PX11 to PXnm display grayscales corresponding to the data voltages.

The gate driver 200 generates gate signals in response to a gate control signal G-CS provided from a timing controller 435. The gate signals are sequentially applied to the pixels PX11 to PXnm through the gate lines GL1 to GLn by row. Therefore, the pixels PX11 to PXnm are operated by row.

The data driver 300 receives the image signals R′G′B′ and a data control signal D-CS. The data driver 300 generates the data voltages corresponding to the image signals R′G′B′ in response to the data control signal D-CS. The data driver 300 applies the data voltages to the pixels PX11 to PXnm through the data lines DL1 to DLm.

The printed circuit board 400 includes the timing controller 435 that controls the operation of the display device 1000. The timing controller 435 receives a plurality of image signals RGB and a plurality of control signals CS from a source external (not shown) to the display device 1000. The timing controller 435 converts the data format of the image signals RGB to a data format appropriate to an interface between the timing controller 435 and the data driver 300 and generates the image signals R′G′B′. The image signals R′G′B′ having the converted data format are applied to the data driver 300.

The timing controller 435 generates a plurality of driving signals in response to the control signals CS. For instance, the timing controller 435 generates the data control signal D-CS and the gate control signal G-CS as the driving signals. The data control signal D-CS may include an output start signal and a clock signal. The gate control signal G-CS may include a vertical start signal and a vertical clock bar signal. The timing controller 435 applies the data control signal D-CS to the data driver 300 and applies the gate control signal G-CS to the gate driver 200. The timing controller 435 applies the gate control signal G-CS to the gate driver 200 through one data circuit board of the data circuit boards 300_1 to 300_k of the data driver 300 shown in FIG. 1.

As described above, the timing controller 435 included in the printed circuit board 400 generates the driving signals and the image signals R′G′B′ for driving the display device 1000. The printed circuit board 400 includes the signal lines for applying the driving signals and the image signals R′G′B′, which are generated by the timing controller 435, to the data driver 300. The signal lines electrically connect the timing controller 435 to the data driver 300.

In general, when the driving signals and the image signals R′G′B′ output from the timing controller 435 are transmitted through the signal lines, an electromagnetic interference (hereinafter, referred as EMI) phenomenon occurs around the signal lines. In particular, when a high frequency signal is transmitted through the signal lines for high-speed operation of the display device 1000, the EMI phenomenon is intensified. As a result, a noise occurs in the image.

However, according to an exemplary embodiment of the present system and method, the printed circuit board 400 may include a shielding layer disposed to overlap with the signal lines. The shielding layer may be disposed to overlap with a pattern layer on which the signal lines are disposed and prevent the EMI from leaking out through the signal lines. The signal lines may be disposed only on the pattern layer, and the printed circuit board 400 may be manufactured without a via hole.

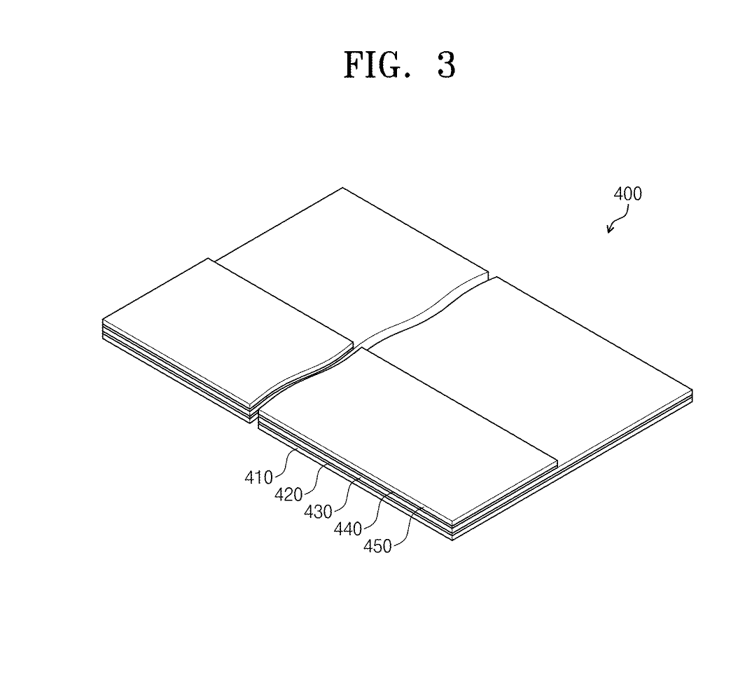

FIG. 3 is a perspective view showing the printed circuit board 400 shown in FIG. 1. Referring to FIGS. 2 and 3, the printed circuit board 400 includes a ground layer 410, a first insulating layer 420, the pattern layer 430, a second insulating layer 440, and the shielding layer 450.

The ground layer 410 is disposed at a lowermost position of the printed circuit board 400 and performs a ground function. The ground layer 410 is disposed over an entire surface of the printed circuit board 400 and includes a signal ground pattern performing the ground function.

The first insulating layer 420 is disposed between the ground layer 410 and the pattern layer 430 and insulates the ground layer 410 from the pattern layer 430.

The pattern layer 430 is disposed on the first insulating layer 420. The timing controller 435 and the signal lines are disposed on the pattern layer 430. The timing controller 435 is connected to one end of the signal lines and the data driver 300 is connected to the other end of the signal lines. The data driver 300 partially overlaps with the pattern layer 430 and connects to the signal lines.

As described with reference to FIG. 2, the timing controller 435 generates the gate control signal G-CS, the data control signal D-CS, and the image signals R′G′B′ for displaying the image. The gate control signal G-CS, the data control signal D-CS, and the image signals R′G′B′, which are output from the timing controller 435, are applied to the data driver 300 through the signal lines.

The second insulating layer 440 is disposed between the pattern layer 430 and the shielding layer 450 to insulate the pattern layer 430 from the shielding layer 450. The second insulating layer 440 is disposed on the pattern layer 430 and has a surface area corresponding to an entire surface of the shielding layer 450.

The shielding layer 450 is disposed on the second insulating layer 440 and has a surface area corresponding to a portion or entire surface of the pattern layer 430. In detail, the shielding layer 450 is disposed at a topmost position of the printed circuit board 400 to shield the EMI generated from the signal lines from being transmitted to the outside of the printed circuit board 400. To this end, the shielding layer 450 is disposed to overlap with the signal lines disposed on the pattern layer 430 and includes a protective ground pattern that performs the ground function.

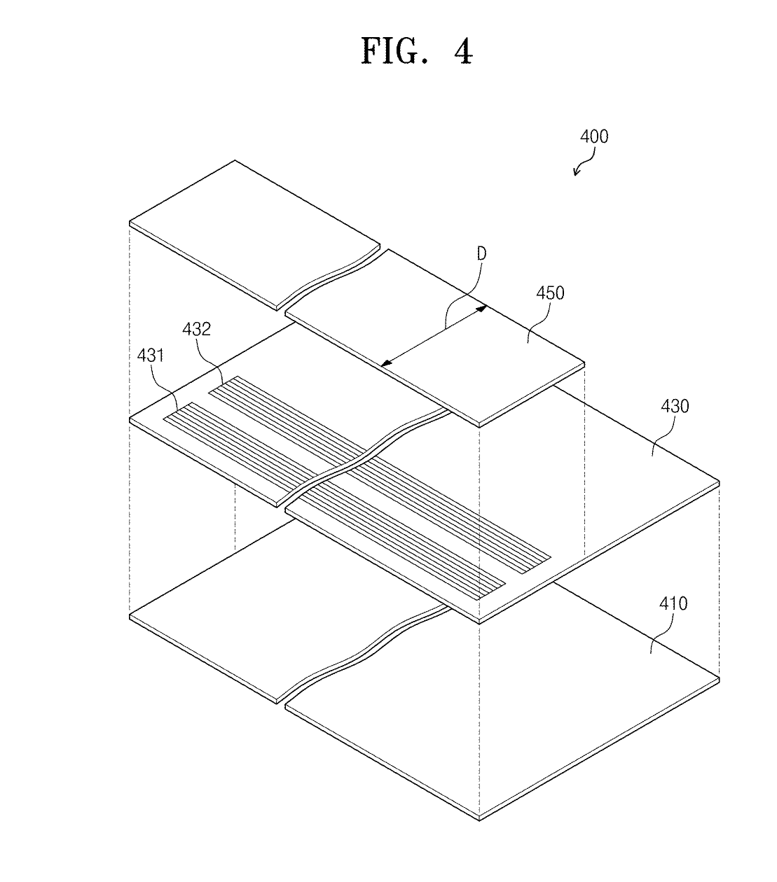

FIG. 4 is an exploded perspective view showing the printed circuit board 400 shown in FIG. 3. Referring to FIG. 4, the ground layer 410, the pattern layer 430, and the shielding layer 450 are sequentially stacked one on another. As shown in FIG. 3, the first insulating layer 420 is disposed between the ground layer 410 and the pattern layer 430, and the second insulating layer 440 is disposed between the pattern layer 430 and the shielding layer 450. The first and second insulating layers 420 and 440, however, are omitted in the following descriptions and not shown in FIG. 4.

As shown in FIG. 4, a first signal pattern 431 and a second signal pattern 432, each of which includes the signal lines, are disposed on the pattern layer 430. The first and second signal patterns 431 and 432 are insulated from each other and electrically connected to the timing controller 435 and the data driver 300, respectively. Although not shown in figures, signal ground patterns insulated from the first and second signal patterns 431 and 432 may be disposed on the pattern layer 430. In addition, the structure in which the first and second signal patterns 431 and 432 are disposed on the pattern layer 430 may be varied without departing from the scope of the present disclosure.

According to the exemplary embodiment of FIG. 4, the shielding layer 450 is disposed to overlap with the first and second signal patterns 431 and 432 disposed on the pattern layer 430. For instance, the pattern layer 430 includes the first and second signal patterns 431 and 432 disposed in an overlapped distance D. That is, the shielding layer 450 is formed according to the overlapped distance D to overlap with the first and second signal patterns 431 and 432.

However, the position at which the shielding layer 450 is disposed is not limited there to or thereby. That is, the shielding layer 450 may be disposed over the entire surface of the pattern layer 430. In addition, the shielding layer 450 may be disposed to overlap with each signal pattern disposed on the pattern layer 430.

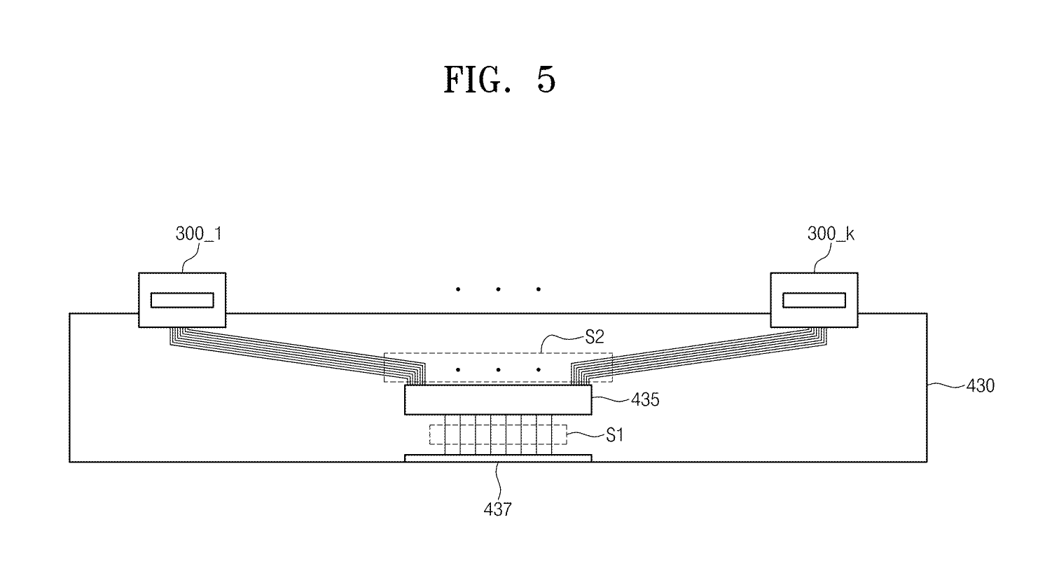

FIG. 5 is a block diagram showing the pattern layer 430 shown in FIG. 4. Referring to FIGS. 4 and 5, the pattern layer 430 includes a plurality of first signal lines 51, a plurality of second signal lines S2, the timing controller 435, and a connector 437.

In more detail, the timing controller 435 is electrically connected to the connector 437 through the first signal lines 51. The timing controller 435 receives the image signals RGB and the control signals CS, which are applied to the first signal lines 51, through the connector 437. For instance, the connector 437 may be electrically connected to an external graphic device (not shown).

The external graphic device may apply the image signals RGB and the control signals CS to the timing controller 435 through the connector 437 using a low voltage differential signaling (LVDS) manner.

The second signal lines S2 are disposed at the first and second signal patterns 431 and 432 shown in FIG. 4. The second signal lines S2 applies the image signals R′G′B′ and the control signals CS from the timing controller 435 to the data circuit boards 300_1 to 300_k. The timing controller 435 applies the image signals R′G′B′, the data control signal D-CS, and the gate control signal G-CS to the data circuit boards 300_1 to 300_k using a differential signaling manner. Here, the data circuit boards 300_1 to 300_k are disposed on a portion of the pattern layer 430 and electrically connected to the second signal lines S2.

According to an exemplary embodiment of the present system and method, the shielding layer 450 is formed to overlap with the first and second signal lines S1 and S2 disposed on the pattern layer 430. That is, the shielding layer 450 is disposed to overlap with the first and second signal lines S1 and S2 to shield the EMI generated in the first and second signal lines S1 and S2.

As described above, the printed circuit board 400 includes the shielding layer 450, which overlaps with the signal lines disposed on the pattern layer 430 as an outermost layer of the printed circuit board 400, to prevent or otherwise reduce EMI phenomenon. In addition, the printed circuit board 400 is manufactured to have a structure that does not include a via hole since the signal lines are disposed on the pattern layer 430.

As a result, the manufacturing process of the display device is simplified and EMI is reduced, thereby improving the driving reliability of the display device 1000.

Although the exemplary embodiments of the present system and method are described herein, the present system and method are not be limited to these exemplary embodiments. Various changes and modifications can be made by one of ordinary skill in the art without departing from the spirit and scope of the present disclosure.

What is claimed is:

1. A printed circuit board comprising:
a ground layer comprising a ground pattern;
a pattern layer disposed on the ground layer and comprising a plurality of signal patterns; and
a shielding layer disposed on the pattern layer and overlapping the signal patterns.

2. The printed circuit board of claim 1, further comprising:
a first insulating layer disposed between the ground layer and the pattern layer; and
a second insulating layer disposed between the pattern layer and the shielding layer.

3. The printed circuit board of claim 1, wherein the pattern layer further comprises a signal ground pattern disposed to be insulated from the signal patterns.

4. The printed circuit board of claim 1, wherein the shielding layer comprises a protective ground pattern that overlaps with the signal patterns.

5. The printed circuit board of claim 1, further comprising a timing controller disposed on the pattern layer and electrically connected to the signal patterns.

6. The printed circuit board of claim 5, wherein the signal patterns comprise first signal patterns and second signal patterns, and the timing controller is electrically connected to the first and second signal patterns.

7. The printed circuit board of claim 6, wherein the timing controller outputs a plurality of image signals and a plurality of driving signals, which are used to display an image, through the first signal patterns.

8. The printed circuit board of claim 6, wherein the timing controller receives a plurality of control signals and a plurality of image data from the outside thereof through the second signal patterns.

9. A display device comprising:
a display panel displaying an image;
a data driver electrically connected to the display panel and outputs a plurality of data voltages to display the image; and
a printed circuit board generating a plurality of image signals corresponding to the data voltages and a plurality of driving signals, the printed circuit board comprising:
a ground layer comprising a ground pattern;
a pattern layer disposed on the ground layer and comprising a plurality of signal patterns; and
a shielding layer disposed on the pattern layer and overlapping the signal patterns.

10. The display device of claim 9, wherein the data driver is electrically connected to the signal patterns disposed on the pattern layer.

11. The display device of claim 9, wherein the shielding layer comprises a protective ground pattern that overlaps with the signal patterns.

12. The display device of claim 9, wherein the printed circuit board further comprises a timing controller to generate the image signals and the driving signals, and the timing controller is disposed on the pattern layer.

13. The display device of claim 12, wherein the timing controller is electrically connected to the signal patterns and applies the image signals and the driving signals to the signal patterns.

14. The display device of claim 13, wherein the timing controller applies the image signals and the driving signals to the signal patterns based on a differential signal.

15. The display device of claim 9, wherein the pattern layer further comprises a signal protective pattern insulated from the signal patterns.
